(19) United States
(12) Patent Application Publication
(10) Pub. No.: US 2008/0303508 A1
(43) Pub. Date: Dec. 11, 2008

(54) Apparatus and Method for Estimating Carrier Frequency Offset in Communication Terminal, and Communication Terminal for Performing the Method

(76) Inventors: Ki Young Kwak, Gyeonggi (KR); Kang Min Lee, Gyeonggi (KR)

Correspondence Address: BLANK ROME LLP, 600 NEW HAMPSHIRE AVENUE, N.W., WASHINGTON, DC, 20037, US

(21) Appl. No.: 12/159,493

(22) PCT Filed: Dec. 28, 2006
(86) PCT No.: PCT/KR06/05804

§ 371 Date: Jun. 27, 2008

(30) Foreign Application Priority Data
Dec. 30, 2005 (KR) 10-2005-0135948

(51) Int. Cl. G01R 23/12

(52) U.S. Cl. 324/76.52

(57) ABSTRACT

Provided are an apparatus and method for estimating carrier frequency offset in a communication terminal operating in a communication system supporting Orthogonal Frequency Division Multiplexing (OFDM) or Orthogonal Frequency Division Multiplexing Access (OFDMA). More particularly, provided are a method of estimating carrier frequency offset in a communication terminal supporting DownLink (DL) Full Usage of SubChannel (FUSC) and DL Band-Adaptive Modulation and Coding (AMC) channel modes in a wireless communication system based on one of Institute of Electrical and Electronic Engineers (IEEE) 802.16d/e, Wireless Broadband (WiBro), and Worldwide interoperability for Microwave Access (WiMAX) standards, and a communication terminal performing the method. The apparatus includes: a phase difference calculator for calculating a phase difference between pilot symbols having the same linear phase among the pilot symbols of a received signal; a phase difference accumulator for accumulating the phase difference and generating a phase difference accumulation value; and a calculator for converting the phase difference accumulation value into a carrier frequency offset estimation value.

### TECHNICAL FIELD

The present invention relates to an apparatus and method for estimating carrier frequency offset in a communication terminal operating in a communication system supporting Orthogonal Frequency Division Multiplexing (OFDM) or Orthogonal Frequency Division Multiplexing Access (OFDMA), and more particularly, to a method of estimating carrier frequency offset in a communication terminal supporting DownLink (DL) Full Usage of SubChannel (FUSC) and DL Band-Adaptive Modulation and Coding (AMC) channel modes in a wireless communication system based on Institute of Electrical and Electronic Engineers (IEEE) 802.16d/e, Wireless Broadband (WiBro), and Worldwide interoperability for Microwave Access (WiMAX) standards, and a communication terminal performing the method.

### BACKGROUND ART

A conventional wireless communication system requires estimating carrier frequency offset by a communication terminal so as to stably receive data. In the wireless communication system supporting one of IEEE 802.16d/e, WiBro, and WiMAX standards, a base station receives a synchronous signal from a global positioning system (GPS), and the communication terminal synchronizes with the base station. Variables existing at a transmission channel such as the rapid change of channel environments result in the inaccuracy of a carrier frequency. This influences an operation of an oscillator within the communication terminal, deteriorating reception performance of the communication terminal. Therefore, the communication terminal needs to estimate the carrier frequency offset, and compensate the carrier frequency offset according to the estimation result.

The present invention proposes a new method of estimating carrier frequency offset, for enhancing reception performance of a communication terminal using a pilot symbol of a received signal transmitted over a downlink channel for the estimation of the carrier frequency offset.

### DISCLOSURE OF INVENTION

### Technical Problem

The present invention is directed to measuring carrier frequency offset for each frame in a communication terminal using a downlink pilot symbol, and compensating for a carrier frequency error of an oscillator using the measurement result, thereby preventing signal reception performance of the communication terminal from deteriorating due to the carrier frequency error.

The present invention is also directed to stably estimating carrier frequency offset in a communication terminal even in unexpected circumstances such as a rapid change of channel environments.

### Technical Solution

One aspect of the present invention provides an apparatus for estimating carrier frequency offset in a communication terminal operating in a communication system supporting Orthogonal Frequency Division Multiplexing (OFDM) or Orthogonal Frequency Division Multiplexing Access (OFDMA). The apparatus includes: a phase difference calculator for calculating a phase difference between pilot symbols having the same linear phase among the pilot symbols of a received signal; a phase difference accumulator for accumulating the phase difference and generating a phase difference accumulation value; and a calculator for converting the phase difference accumulation value into a carrier frequency offset estimation value.

Another aspect of the present invention provides a method of estimating carrier frequency offset in a communication terminal operating in a communication system supporting Orthogonal Frequency Division Multiplexing (OFDM) or Orthogonal Frequency Division Multiplexing Access (OFDMA). The method includes the steps of: calculating a phase difference between pilot symbols having the same linear phase among the pilot symbols of a received signal; accumulating the phase difference, and generating a phase difference accumulation value; and converting the phase difference accumulation value into a carrier frequency offset estimation value.

### ADVANTAGEOUS EFFECTS

As described above, according to an apparatus and method for estimating carrier frequency offset in a communication terminal of the present invention, it is possible to measure the carrier frequency offset for each frame in a communication terminal using a downlink pilot symbol and compensate for a carrier frequency error of an oscillator using the measured result, thereby preventing reception performance from deteriorating due to the carrier frequency error.

According to the apparatus and method for estimating carrier frequency offset in the communication terminal, the carrier frequency offset can be stably estimated even in unexpected circumstances such as a rapid change of channel environments, thereby guaranteeing stable operation of the communication terminal.

### BRIEF DESCRIPTION OF THE DRAWINGS

FIG. 1 is a schematic diagram of an OFDM/OFDMA transceiver;

FIG. 2 is a block diagram of an apparatus for estimating carrier frequency offset in a communication terminal according to an exemplary embodiment of the present invention;

FIG. 3 is a diagram illustrating a pilot symbol location based on a DL FUSC channel mode;

FIG. 4 is a diagram illustrating a pilot symbol location based on a 2 bins by 3 symbols type DL Band-AMC channel mode;

FIG. 5 is a diagram illustrating an example of a method of calculating a phase difference between pilot symbols having the same location in a frequency domain, in a DL FUSC channel mode;

FIG. 6 is a diagram illustrating an example of a method of calculating a phase difference between pilot symbols having the same location in a frequency domain, in a 2 bins by 3 symbols type DL Band-AMC channel mode;

FIG. 7 is a flowchart illustrating a method of estimating carrier frequency offset in a communication terminal according to an exemplary embodiment of the present invention; and

FIG. 8 is a graph illustrating a simulation result of a method of estimating carrier frequency offset in a communication terminal according to an exemplary embodiment of the present invention.

### DESCRIPTION OF MAJOR SYMBOLS IN THE ABOVE FIGURES

201: FFT unit
202: Phase difference calculator
203: Phase difference accumulator
204: Arc-tangent calculator
205: Conversion calculator
206: Averaging calculator
207: Oscillator

### MODE FOR THE INVENTION

In this specification, “Communication terminal” refers to a communication terminal supporting Orthogonal Frequency Division Multiplexing (OFDM) or Orthogonal Frequency Division Multiplexing Access (OFDMA). Desirably, “communication terminal” refers to a communication terminal supporting DownLink (DL) Full Usage of SubChannel (FUSC) and DL Band-Adaptive Modulation and Coding (AMC) channel modes in a wireless communication system based on Institute of Electrical and Electronic Engineers (IEEE) 802.16d/e, Wireless Broadband (WiBro), Worldwide interoperability for Microwave Access (WiMAX) standards.

In this specification, “Wireless communication system” can represent a system based on any one of the IEEE 802.16d/e, WiBro, and WiMAX standards.

In this specification, “Symbol” refers to an OFDMA or OFDM symbol.

Hereinafter, an apparatus and method for estimating carrier frequency offset in a communication terminal operating in a communication system according to exemplary embodiments of the present invention, and a communication terminal performing the method will be described in detail with reference to the accompanying drawings.

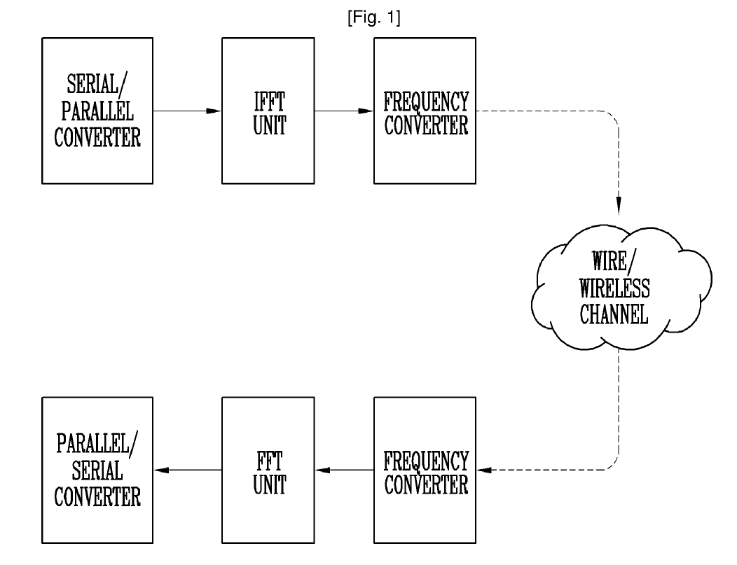

FIG. 1 is a schematic diagram of an OFDM/OFDMA transceiver.

As shown in FIG. 1, the OFDM/OFDMA transceiver includes serial/parallel converters, Fast Fourier Transform (FFT) and Inverse Fast Fourier Transform (IFFT) units, and frequency converters.

In a transmission stage, the serial/parallel converter receives and converts a serial data stream into parallel data streams corresponding to the number of sub-carriers. The IFFT unit performs inverse Fourier transform for each parallel data stream. The inverse Fourier transformed data is again converted into serial data, and is frequency-converted and transmitted. A reception stage receives a signal over a wire/wireless channel, demodulates the received signal inversely to the transmission stage, and outputs data.

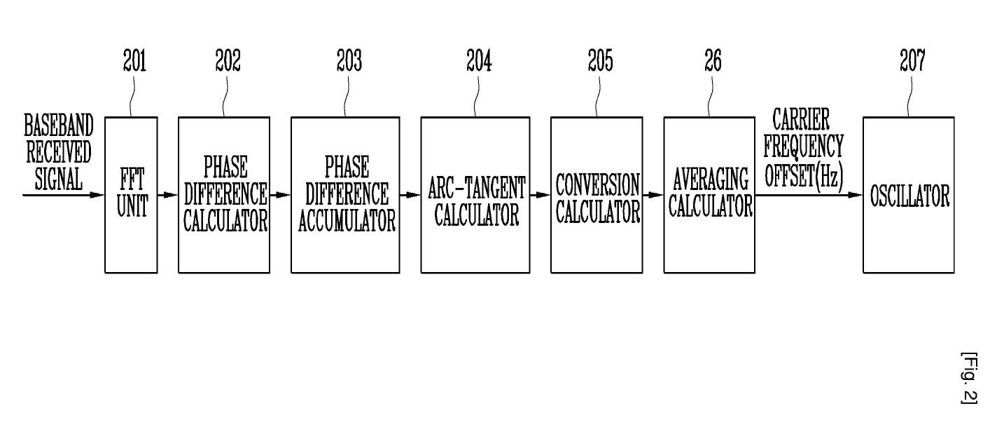

FIG. 2 is a block diagram of an apparatus for estimating carrier frequency offset in a communication terminal according to an exemplary embodiment of the present invention.

The apparatus for estimating carrier frequency offset according to the present invention includes an FFT unit 201, a phase difference calculator 202, a phase difference accumulator 203, an arc-tangent calculator 204, a conversion calculator 205, and an averaging calculator 206. The FFT unit 201 can be excluded from the estimating apparatus according to need. In this case, the apparatus for estimating carrier frequency offset according to the present invention uses a signal undergoing a pre-processing process of performing FFT for a baseband received signal and performing transformation into a frequency domain.

The received signal whose time domain is transformed into the frequency domain using the FFT unit 201 of FIG. 2 includes a preamble signal used for initial synchronization or cell search, a pilot symbol used for channel and synchronization estimation, and a data symbol including actual data. The communication terminal according to the present invention estimates the carrier frequency offset using the pilot symbol among the above signals.

The apparatus for estimating carrier frequency offset according to the present invention will be in detail described with reference to FIG. 2 below.

The time domain of the baseband received signal transitions to the frequency domain through the FFT unit 201. The pilot symbol is extracted from the received signal Fourier transformed in the FFT unit 201, with reference to structure of a downlink channel. A predetermined pilot sequence can be correlated to a plurality of sub-carriers on the received signal that is an OFDM or OFDMA signal to extract the pilot symbol, and thus the pilot symbol can be acquired from a correlation value for the plurality of sub-carriers. In other words, the pilot symbol is predetermined in its transmission location depending on the downlink channel/channel mode in the communication system supporting the OFDM/OFDMA and thus, the pilot symbol can be extracted in such a manner that the predetermined pattern pilot sequence is correlated to the sub-carrier of the received signal.

The phase difference calculator 202 calculates a phase difference between the pilot symbols having the same location in the frequency domain. The reason for calculating the phase difference between the pilot symbols having the same location in the frequency domain is that the pilot symbols have the same linear phase. The calculation of the phase difference between the pilot symbols that are how distant from each other in the time domain (“inter-pilot-symbol distance” to be described later) can be different depending on the structure of the downlink channel, and variable depending on a range and a calculation quantity of the carrier frequency offset to be measured.

A basic principle of the carrier frequency offset estimating apparatus according to the present invention is to generate a carrier frequency offset estimation value using the phase difference between the pilot symbols. In the present invention, the interpilot-symbol distance for calculating the phase difference can be a matter of importance. An estimatable frequency band gets smaller as the inter-pilot-symbol distance for calculating the phase difference increases. The calculation quantity needed to acquire the phase difference gets greater as the inter-pilot-symbol distance for calculating the phase difference decreases, thereby increasing a system load. Accordingly, it is important to predetermine a suitable inter-pilot-symbol distance.

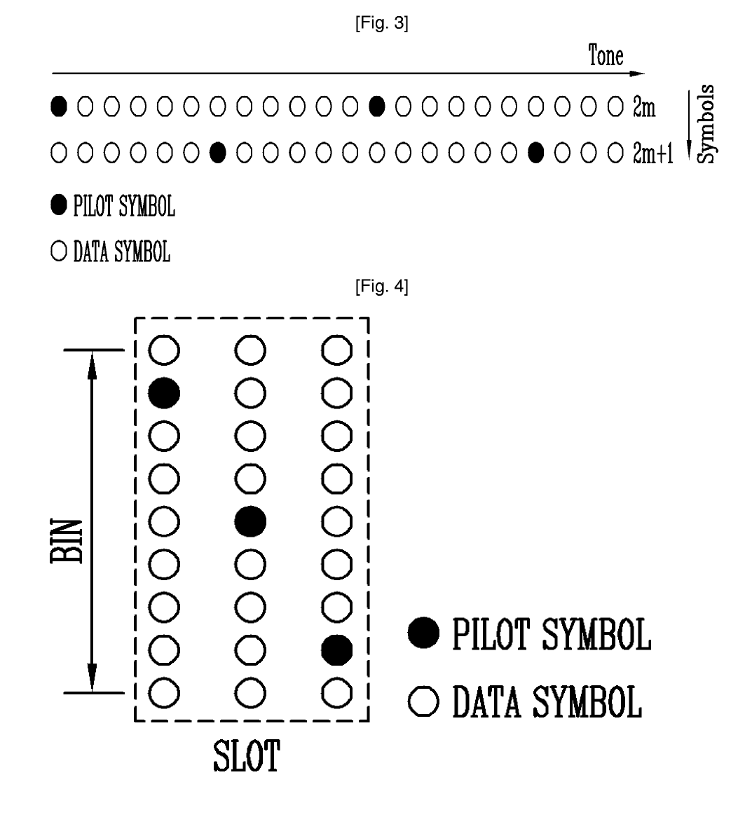

FIG. 3 is a diagram illustrating a pilot symbol location decided by a variable set in a DL FUSC channel mode.

Referring to FIG. 3, the pilot symbol location in the DL FUSC channel mode is decided by the variable set and a constant set. The constant set constantly fixes and designates the pilot symbol location. The variable set designates the pilot symbol location by a predetermined function. The function of deciding the pilot symbol location (PilotLocation) in the variable set is as follows:

PilotLocation=VariableSet#+6*(FUSC_SymbolNumber %2).

In the function, each parameter varies depending on an FFT size. A real value can refer to the IEEE 802.16d/e, WiBro, and WiMAX standards. The pilot symbol location of FIG. 3 is decided using the function illustrated above.

FIG. 4 is a diagram illustrating a pilot symbol location based on a 2 bins by 3 symbols type DL Band-AMC channel mode.

Referring to FIG. 4, a basic unit of the DL Band-AMC channel mode is “bin”. A single specific sub-carrier is assigned to the pilot symbol within the bin constituting nine contiguous sub-carriers. The pilot symbol location is different depending on a symbol index within the bin. There exist several types of sub channel structures in the Band-AMC channel mode. FIG. 4 illustrates a 2 bins by 3 symbols type sub channel structure.

As described in detail with reference to FIGS. 3 and 4, the pilot symbol location varies during an arbitrary symbol duration in the time domain in the DL FUSC or DL Band-AMC channel mode that is a downlink channel mode. A pattern of the pilot symbol location is identically repeated in periods based on the arbitrary symbol duration. Basically, in the DL FUSC channel mode, the pilot symbol location varies during two symbol durations in the time domain, and the same pattern is repeated in periods based on the two symbol durations. In the 2 bins by 3 symbols type DL Band-AMC channel mode, the pilot symbol location varies during three symbol durations in the time domain, and the same pattern is repeated in periods based on the three symbol durations.

In other types of DL Band-AMC channel modes, there is a pattern suitable to a corresponding structure. A minimal interval for calculating the phase difference in the time domain is “2” in the DL FUSC channel mode. A minimal interval for calculating the phase difference in the time domain is “3” in the 2 bins by 3 symbols type DL Band-AMC channel mode.

In other words, the pilot symbol locations are different from each other within a period of a predetermined time domain in the downlink channel mode, and the pilot pattern is repeated in periods based on the time domain. Thus, it is desirable to use a periodicity of the repeated pattern to calculate the phase difference between the pilot symbols having the same position in the frequency domain. As described above, the inter-pilot-symbol distance in the time domain can be “2” in the DL FUSC channel mode. The inter-pilot-symbol distance can be “3” in the 2 bins plus 3 symbols type DL Band-AMC channel mode. In particular, the inter-pilot-symbol distance can vary depending on the type of the DL Band-AMC channel mode as described above. As such, the inter-pilot-symbol distance for calculating the phase difference can be flexibly set depending on an embodiment view, or the range of the carrier frequency offset to be measured. Thus, a value of “d” in Equation 1 can be decided as described above.

$${f}_{current} [ Hz ] = {f}_{pre} + α \cdot Gain \cdot {tan}^{- 1} \{ {\sum }_{n} {\sum }_{j} {p}_{j} ( n ) \cdot {p}_{j}^{*} ( n - d ) \} \qquad ( Equation 1 )$$

Each parameter of Equation 1 is defined as follows:

(1) j: index of pilot sub-carrier per symbol;

(2) n: symbol index within a DL zone;

(3) d: inter-pilot-symbol distance for calculating the phase difference between the two pilot symbols;

(4) f_{current}: carrier frequency offset estimation value measured at a current frame;

(5) fₚᵣₑ: carrier frequency offset estimation value averaged and calculated up to a pre previous frame;

(6) Gain: parameter for transitioning a phase value having a radian unit to a value having a frequency unit; and

(7) α: filter coefficient in the case of using a loop filter for averaging calculation.

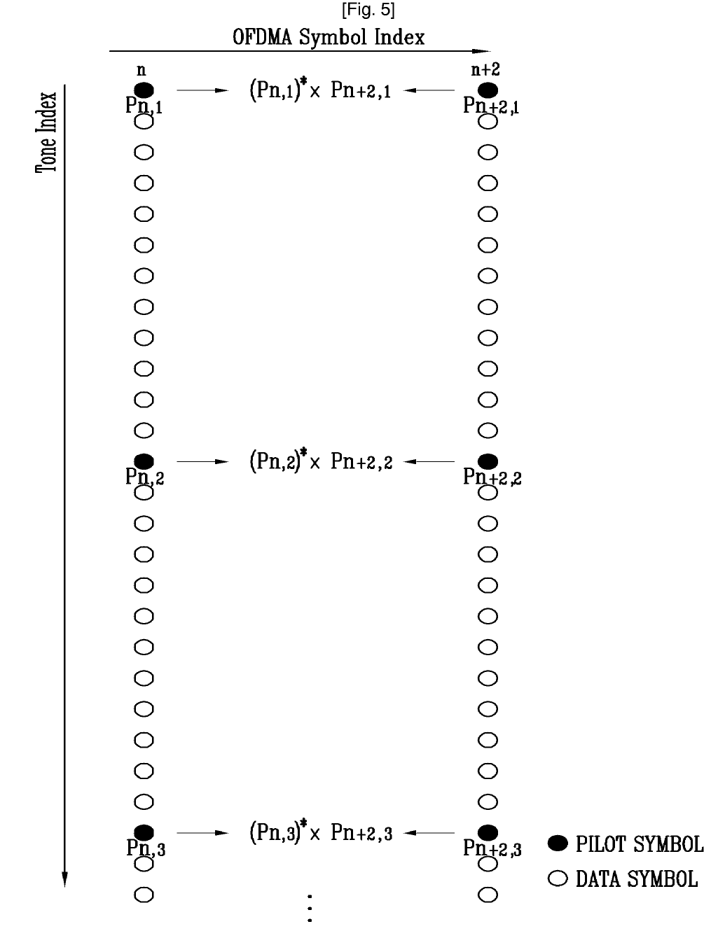

FIG. 5 is a diagram illustrating an example of a method of calculating the phase difference between the pilot symbols having the same location in the frequency domain in the DL FUSC channel mode. FIG. 5 illustrates the method of calculating the phase difference between the pilot symbols where the inter-pilot-symbol distance is “2” in the DL FUSC channel mode. It has been confirmed that offset estimation at a range of about 2.7 KHz can be achieved in the method of FIG. 5.

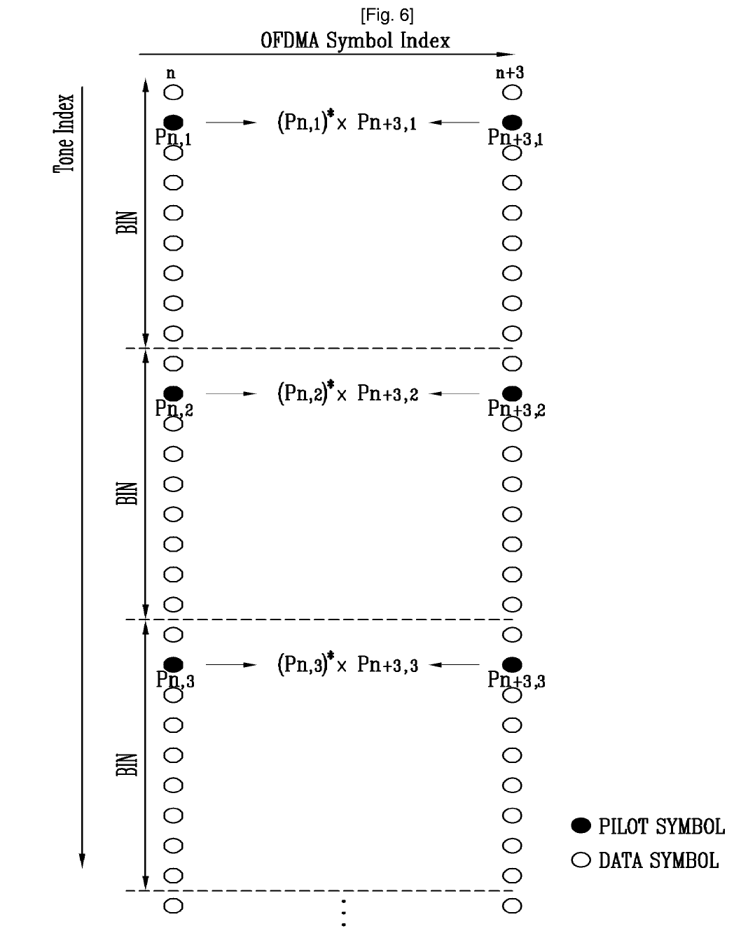

FIG. 6 is a diagram illustrating an example of a method of calculating the phase difference between the pilot symbols having the same location in the frequency domain, in the 2 bins by 3 symbols type DL Band-AMC channel mode. FIG. 6 illustrates an example of the method of calculating the phase difference between the pilot symbols where the inter-pilot-symbol distance is “3” in the 2 bins by 3 symbols type DL Band-AMC channel mode. It has been confirmed that offset estimation at a range of about 1.7 KHz can be achieved in the method of FIG. 6.

FIGS. 5 and 6 illustrate examples of calculating the phase difference between the two pilot symbols having the same location, i.e., the same linear phase in the frequency domain. However, in another exemplary embodiment of the present invention, a method of calculating a phase difference between two pilot symbols having different linear phases can be provided by adding a suitable calibration value to one of the two pilot symbols and identically calibrating the linear phases of the two pilot symbols.

The phase difference accumulator 203 accumulates and calculates the phase difference measured at each pilot symbol, and outputs a first phase difference accumulation value having a complex number unit to the arc-tangent calculator 204.

The arc-tangent calculator 204 converts the first phase difference accumulation value having the complex number unit into a second phase difference accumulation value having a radian unit. The arc-tangent calculation can, for example, use a LookUp Table (LUT) technique. In a case where the LUT technique is used, the arc-tangent calculation can be performed in such a manner that the second phase difference accumulation value having the radian unit corresponding to the first phase difference accumulation value having the complex number unit is recorded on an LUT, and the second phase difference accumulation value having the radian unit corresponding to the first phase difference accumulation value having the complex number unit is read with reference to the LUT, depending on the first phase difference accumulation value having the complex number unit that is input by the phase difference accumulator 203.

In another exemplary embodiment of the present invention, an arc-tangent calculator 204 can convert a first phase difference accumulation value having a complex number unit into a second phase difference accumulation value having a radian unit, using various arc-tangent calculation algorithms such as Cordic algorithm.

The conversion calculator 205 converts the second phase difference accumulation value having the radian unit, which is converted in the arc-tangent calculator 204, into the carrier frequency offset estimation value that is the value having the frequency unit.

In yet another exemplary embodiment of the present invention, the conversion calculator 205 can be omitted in a case where an apparatus for estimating carrier frequency offset in a communication terminal estimates carrier frequency offset using a second phase difference accumulation value having a radian unit, that is, in a case where an oscillator 207 of the communication terminal is controlled by the second phase difference accumulation value having the radian unit.

The communication terminal generates the carrier frequency offset estimation value through the FFT unit 201 to the conversion calculator 205. The carrier frequency offset estimation value is used as a criterion signal for controlling the oscillator 207 of the communication terminal.

In yet another exemplary embodiment of the present invention, the carrier frequency offset estimating apparatus can further include an averaging calculator 206 so that it can stably estimate the carrier frequency offset in the communication terminal. The averaging calculator 206 can average and calculate the carrier frequency offset estimation value measured for each frame, thereby stably estimating the carrier frequency offset even in a case where the carrier frequency offset measured by the communication terminal is inaccurate due to a rapid change in channel environments.

The averaging calculation executed by the averaging calculator 206 can use the loop filter. Alternately, the averaging calculation can use various algorithms including a method of averaging the carrier frequency offset estimation value that the communication terminal measures for a predetermined frame.

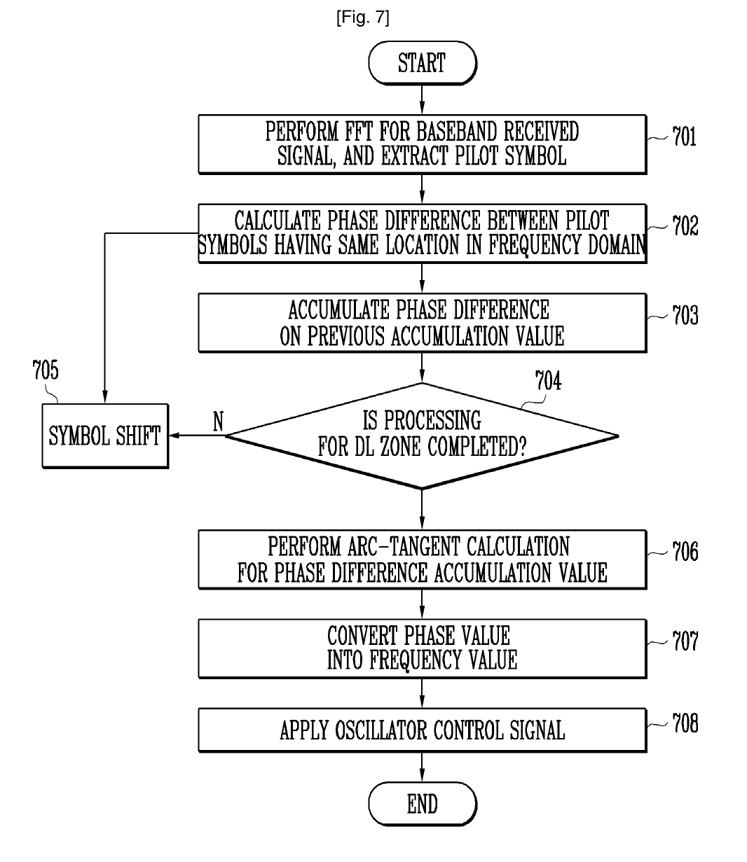

FIG. 7 is a flowchart illustrating a method of estimating carrier frequency offset in a communication terminal according to an exemplary embodiment of the present invention.

Referring to FIG. 7, the method of estimating carrier frequency offset in the communication terminal according to the present invention can include the following steps.

The baseband received signal of the time domain is Fourier transformed, its time domain is transitioned to the frequency domain, and the pilot symbol is extracted from the Fourier transformed received signal (Step 701). As described above with reference to FIG. 2, the predetermined pilot sequence can be correlated to the plurality of sub-carriers on the received signal and thus, the pilot symbol can be acquired from the correlation value for the plurality of sub-carriers.

Next, the phase difference between the pilot symbols having the same location in the frequency domain is calculated (Step 702). The reason for calculating the phase difference between the pilot symbols having the same location in the frequency domain is that the pilot symbols have the same linear phase. The inter-pilot-symbol distance for calculating the phase difference can be a matter of importance. The inter-pilot-symbol distance can be different depending on the structure of the downlink channel, and is variable depending on the range and the calculation quantity of the carrier frequency offset to be measured. A description of Step 702 is substituted with a detailed description of FIG. 2.

The phase difference measured at each pilot symbol having the same location in the frequency domain is accumulated on a previous phase difference accumulation value (Step 703). Steps 702 and 703 can be repeated until they are performed for all the pilot symbols of the DL zone (Steps 704 and 705).

In Step 704, it is determined whether the calculation of the phase difference accumulation value for all the pilot symbols within the DL zone is completed. Then, the arc-tangent calculation is performed to convert the first phase difference accumulation value having the complex number unit into the second phase difference accumulation value having the radian unit (Step 706). A detailed description of the arc-tangent calculation of Step 706 is substituted with the description of FIG. 2. The second phase difference accumulation value having the radian unit generated as the result of the arc-tangent calculation of Step 706 is converted into the carrier frequency offset estimation value that is the value having the frequency unit (Step 707).

Step 707 can be omitted in a case where the carrier frequency offset is compensated using the second phase difference accumulation value having the radian unit, that is, in a case where the oscillator of the communication terminal is controlled by the second phase difference accumulation value having the radian unit in the estimating method according to another exemplary embodiment of the present invention aforementioned with reference to FIG. 2.

The communication terminal generates the carrier frequency offset estimation value through Steps 701 to 707. The carrier frequency offset estimation value is used as the criterion signal for controlling the oscillator of the communication terminal (Step 708).

In yet another exemplary embodiment of the present invention, the method of estimating carrier frequency offset can further include the step of performing the averaging calculation to stably estimate the carrier frequency offset in the communication terminal. As described above, the averaging calculation enables the stable estimation of the carrier frequency offset even in a case where the carrier frequency offset measured by the communication terminal is inaccurate due to a rapid change in the channel environments.

The method of estimating carrier frequency offset by measuring the phase difference between the pilot symbols in the communication terminal according to the present invention can be realized in a program command form executable by various computer means, and can be recorded in a computer readable medium. The computer readable medium can include a program command, a data file, and a data structure singly or in combination. The program command recorded in the computer readable medium can be a command particularly designed for the present invention, or can be a command well known to and available by those skilled in the computer software art. The computer readable recording medium includes magnetic media such as a hard disc, a floppy disc, and a magnetic tape, optical media such as Compact Disc-Read Only Memory (CD-ROM) and Digital Versatile Disc (DVD), magneto-optical media such as a floptical disk, and a hardware device particularly constructed to store and execute the program command such as Read Only Memory (ROM), Random Access Memory (RAM), and flash memory, for example. The media can be transmission media such as light, a metal line, or a wave guide that include a carrier carrying a signal designating the program command and the data structure. The program command includes a machine language code compiled by a compiler as well as a high-level language code executable by a computer using an interpreter, for example. The hardware device can be constructed and operated as one or more software modules so as to execute the operation of the present invention, and vice versa.

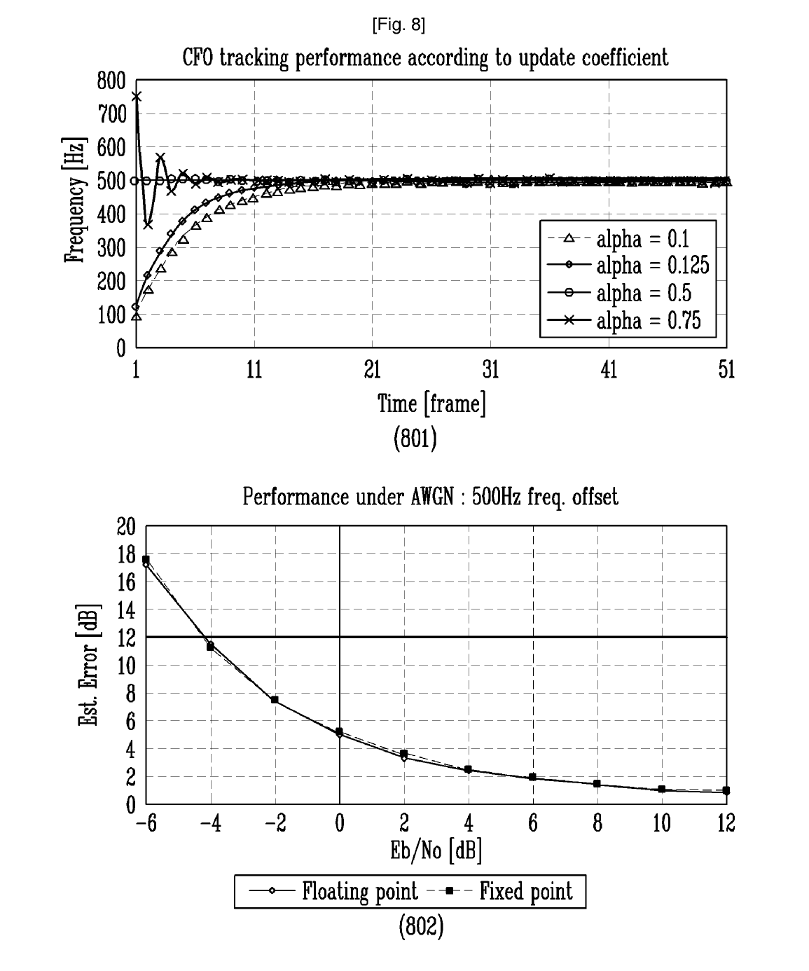

FIG. 8 is a graph illustrating a simulation result of the method of estimating carrier frequency offset in the communication terminal according to an exemplary embodiment of the present invention.

The graph of the simulation result shown in FIG. 8 is based on the assumption that a channel is Additive White Gaussian Noise (AWGN), and a target carrier frequency offset is 500 Hz.

A graph 801 of FIG. 8 represents a tracking result of the carrier frequency offset according to a coefficient of an Infinite Impulse Response (IIR) filter in the DL FUSC channel mode. In this simulation, the inter-pilot-symbol distance was “2” and “Alpha” shown in the graph refers to a coefficient of the IIR filter. In the graph 801 of FIG. 8 it can be appreciated that a response speed gets somewhat lower when the alpha is small and a transient response gets greater when the alpha is great.

A graph 802 of FIG. 8 represents a simulation result based on a Mean Square Error (MSE) in the DL Band-AMC channel mode. In the graph 802, a floating point indicates an MSE result under ideal circumstances, and a fixed point indicates an MSE result obtained by applying a carrier frequency offset estimation algorithm according to the present invention. In this simulation, the inter-pilot-symbol distance was “3”. In the graph 802 of FIG. 8, it can be appreciated that the almost same result as the MSE result under ideal circumstances is calculated as a result of using the carrier frequency offset estimation algorithm according to the present invention.

While the invention has been shown and described with reference to certain exemplary embodiments thereof, it will be understood by those skilled in the art that various changes in form and details may be made therein without departing from the spirit and scope of the invention as defined by the appended claims.

1. An apparatus for estimating carrier frequency offset in a communication terminal operating in a communication system supporting Orthogonal Frequency Division Multiplexing (OFDM) or Orthogonal Frequency Division Multiplexing Access (OFDMA), the apparatus comprising:
a phase difference calculator for calculating a phase difference between pilot symbols having the same linear phase among the pilot symbols of a received signal;
a phase difference accumulator for accumulating the phase difference and generating a phase difference accumulation value; and
a calculator for converting the phase difference accumulation value into a carrier frequency offset estimation value.

2. The apparatus of claim 1, wherein the frequency offset estimation value is a value having a radian unit.

3. The apparatus of claim 1, wherein the frequency offset estimation value is a value having a frequency unit.

4. The apparatus of claim 3, wherein the calculator comprises:
an arc-tangent calculator for performing arc-tangent calculation for the phase difference accumulation value and converting the phase difference accumulation value into a second phase difference accumulation value; and
a conversion calculator for converting the second phase difference accumulation value into the value having the frequency unit.

5. The apparatus of claim 4, wherein the arc-tangent calculator comprises a lookup table (LUT) for recording at least one phase difference accumulation value and the second phase difference accumulation value corresponding to the phase difference accumulation value, and the arc-tangent calculator reads the second phase difference accumulation value corresponding to the phase difference accumulation value with reference to the LUT.

6. The apparatus of claim 4, wherein the arc-tangent calculator converts the phase difference accumulation value into the second phase difference accumulation value using Cordic algorithm.

7. The apparatus of claim 1, further comprising an averaging calculator for generating an average value for the carrier frequency offset estimation value measured at each frame of the received signal.

8. The apparatus of claim 7, wherein the averaging calculator uses a loop filter.

9. The apparatus of claim 1, wherein when the linear phases of the pilot symbols are not the same, the phase difference calculation module calibrates the linear phase of the pilot symbol using a predetermined calibration value and then calculates the phase difference of the pilot symbol.

10. The apparatus of claim 1, wherein the communication system is a system based on any one of Institute of Electrical and Electronic Engineers (IEEE) 802.16d/e, Wireless Broadband (WiBro), and Worldwide interoperability for Microwave Access (WiMAX) standards.

11. The apparatus of claim 10, wherein the pilot symbol is constructed using a symbol structure associated with any one of Downlink (DL) Full Usage of SubChannel (FUSC) and DL Band-Adaptive Modulation and Coding (AMC) channel modes.

12. The apparatus of claim 11, wherein the phase difference accumulator accumulates the phase difference between the pilot symbols at each DL zone associated with the channel mode.

13. The apparatus of claim 1, wherein the received signal is a baseband signal, and the apparatus further comprises a Fast Fourier Transform (FFT) unit for Fourier transforming the baseband signal.

14. A communication terminal operating in a communication system supporting Orthogonal Frequency Division Multiplexing (OFDM) or Orthogonal Frequency Division Multiplexing Access (OFDMA), the terminal comprising:
a receiver for receiving a downlink signal from the communication system; and
a carrier frequency offset estimating apparatus for extracting a pilot symbol from the downlink signal, calculating a phase difference between the pilot symbols having the same linear phase among the extracted pilot symbols, and generating a carrier frequency offset estimation value.

15. The communication terminal of claim 14, wherein the pilot symbol is constructed using a symbol structure associated with any one of Downlink (DL) Full Usage of SubChannel (FUSC) and DL Band-Adaptive Modulation and Coding (AMC) channel modes.

16. A method of estimating carrier frequency offset in a communication terminal operating in a communication system supporting Orthogonal Frequency Division Multiplexing (OFDM) or Orthogonal Frequency Division Multiplexing Access (OFDMA), the method comprising the steps of:
calculating a phase difference between pilot symbols having the same linear phase among the pilot symbols of a received signal;
accumulating the phase difference, and generating a phase difference accumulation value; and
converting the phase difference accumulation value into a carrier frequency offset estimation value.

17. The method of claim 16, wherein the frequency offset estimation value is a value having a radian unit.

18. The method of claim 16, wherein the frequency offset estimation value is a value having a frequency unit.

19. The method of claim 18, further comprising the steps of:
performing arc-tangent calculation for the phase difference accumulation value, and converting the phase difference accumulation value into a second phase difference accumulation value having a radian unit; and
converting the second phase difference accumulation value into a value having a frequency unit.

20. The method of claim 16, further comprising the step of generating an average value for the carrier frequency offset estimation value measured at each frame of the received signal.

21. The method of claim 16, wherein the step of calculating the phase difference between the pilot symbols is performed after the step of Fourier transforming the received signal.

22. The method of claim 16, wherein the communication system is a system based on any one of Institute of Electrical and Electronic Engineers (IEEE) 802.16d/e, Wireless Broadband (WiBro), and Worldwide interoperability for Microwave Access (WiMAX) standards.

23. The method of claim 22, wherein the pilot symbol is constructed using a symbol structure associated with any one of Downlink (DL) Full Usage of SubChannel (FUSC) and DL Band-Adaptive Modulation and Coding (AMC) channel modes.

24. The method of claim 23, wherein the phase difference between the pilot symbols is accumulated at each DL zone associated with the channel mode.

25. A method of estimating carrier frequency offset in a communication terminal operating in a communication system supporting Orthogonal Frequency Division Multiplexing (OFDM) or Orthogonal Frequency Division Multiplexing Access (OFDMA), the method comprising the steps of:
receiving a downlink signal from the communication system;
extracting a pilot symbol from the downlink signal; and
calculating a phase difference between the pilot symbols having the same linear phase among the extracted pilot symbols, and generating a carrier frequency offset estimation value.

26. A computer readable recording medium which records a program for implementing the method of claim 16.
